(19) United States
(12) Patent Application Publication
(10) Pub. No.: US 2015/0207009 A1
(43) Pub. Date: Jul. 23, 2015

(54) PHOTOVOLTAIC SYSTEM WITH STACKED SPECTRUM SPLITTING OPTICS AND PHOTOVOLTAIC ARRAY TUNED TO THE RESULTING SPECTRAL SLICES PRODUCED BY THE SPECTRUM SPLITTING OPTICS

(71) Applicants: DOW GLOBAL TECHNOLOGIES LLC, Midland, MI (US); CALIFORNIA INSTITUTE OF TECHNOLOGY, Pasadena, CA (US)

(72) Inventors: Matthew D. Escarra, Pasedena, CA (US); Sunita Darbe, Pasadena, CA (US); Harry A. Atwater, South Pasadena, CA (US); Rebekah K. Feist, Midland, MI (US); Carrie E. Hofmann, Altadena, CA (US); Emily D. Kosten, Pasadena, CA (US); Michael E. Mills, Midland, MI (US); Narayan Ramesh, Midland, MI (US); James C. Stevens, Richmond, TX (US)

(21) Appl. No.: 14/424,269

(22) PCT Filed: Aug. 30, 2013
(86) PCT No.: PCT/US13/57535

§ 371 Date: Feb. 26, 2015

Related U.S. Application Data
(60) Provisional application No. 61/695,216, filed on Aug. 30, 2012.
(60) Provisional application No. 61/745,267, filed on Dec. 21, 2012.

(51) Int. Cl. H01L 31/054

(52) U.S. Cl. CPC H01L 31/0549

(57) ABSTRACT

The present invention provides photovoltaic devices that comprise multiple bandgap cell arrays in combination with spectrum splitting optics. The spectrum splitting optics include one or more optical spectrum splitting modules that include two or more optical splitting, diffractive elements that are optically in series to successively and diffractively split incident light into segments or slices that are independently directed onto different photovoltaic cell(s) of the array having appropriate bandgap characteristics.

### PRIORITY

The present patent application claims priority from United States Provisional patent application having Ser. No. 61/695,216, filed on Aug. 30, 2012, entitled OPTICS FOR FULL SPECTRUM, ULTRAHIGH EFFICIENCY SOLAR ENERGY CONVERSION, and United States Provisional patent application having Ser. No. 61/745,267, filed on Dec. 21, 2012, entitled PHOTOVOLTAIC SYSTEM WITH STACKED SPECTRUM SPLITTING OPTICS AND PHOTOVOLTAIC ARRAY TUNED TO THE RESULTING SPECTRAL SLICES PRODUCED BY THE SPECTRUM SPLITTING OPTICS, wherein the entirety of said provisional patent applications is incorporated herein by reference.

### TECHNICAL FIELD

The present invention relates to photovoltaic devices that convert incident light into electrical energy. More specifically, the present invention relates to photovoltaic devices including an array of photovoltaic cells having multiple bandgaps used in combination with spectrum splitting optics that partition incident light into segments (or slices) and then direct the segments onto photovoltaic cell(s) of the array with appropriate, corresponding bandgaps.

### BACKGROUND

A photovoltaic cell (also referred to as a solar cell or a PV cell) converts incident light, such as sunlight, into electrical energy. Unfortunately, many individual photovoltaic cells tend to convert light into electric energy at lower efficiencies than is desired. Cell efficiency is limited by several factors.

As one factor, a single junction photovoltaic cell has a characteristic energy gap (also referred to as a bandgap) that represents a minimum amount of energy that a photon must have in order for the photon to be converted into electrical energy by the cell. Many light sources, including the sun, emit broad spectral distributions of photons. The broadband spectra of such light sources include photons whose energy is below the energy gap, photons whose energy matches the energy gap, and photons whose energy is greater than the energy gap. Only photons having an energy that matches the energy gap are used most efficiently. Photons whose energy is lower than the gap are reflected, transmitted, or absorbed and converted to wasted heat. Photons with energy greater than the gap convert only part of their energy matching the energy gap into electrical energy while the excess energy is lost mainly as wasted heat.

Consequently, a single photovoltaic cell converts only a small portion of incident light into electrical energy due to the fact that the cell is optimally photovoltaically responsive only to a small portion of the broadband spectrum of the incident light. Theoretically, at most 33.4% for the AM1.5D (direct) spectrum could be converted into electrical energy. See, e.g., Martin Green, “Limiting photovoltaic efficiency under new ASTM International G173-based reference spectra”, Progress in Photovoltaics (2011) Vol 20, p 954.

In view of this limitation upon the ability of a single photovoltaic cell to be adequately responsive to a broadband spectrum, photovoltaic devices incorporating an array of cells having multiple bandgaps are known. Further, spectrum splitting optics are used to split the broadband spectrum into two or more narrower spectral bands (also referred to as spectral slices, portions, or components). The narrower bands are directed to cell(s) with different bandgaps. Each targeted cell is designed to have a bandgap tailored to the spectral band directed to it in order to help optimize energy conversion. In short, the splitting optics partition the incident light into segments or slices and then direct the slices independently to those PV cell(s) with appropriate bandgaps. For example, a spectral band associated with higher energy light is directed to PV cells with relatively higher bandgaps optimized for higher energy light conversion, and a spectral band associated with lower energy light is directed to PV cells with relatively lower bandgaps optimized for lower energy light conversion. Systems have been described that use 2, 3, or more spectral slices in this manner.

Photovoltaic systems with multi-bandgap and spectrum splitting features have been described in the patent and technical literature. Examples include U.S. Pat. Nos. 4,418,238; 5,517,339; 4,021,267 and 4,204,881; U.S. Pat. Pub. No. 2011/0284054; Fixler et. al., J. of Photons for Energy, “Spectral Separation of Sunlight for Enhanced Operability of Photovoltaic Cells,” Vol. 1, 2011; Stefancich, Optics Express, “Single Element Spectral Splitting Solar Concentrator for Multiple Cells CPV System,” Vol. 20, No. 8, pp. 9004-9018 (2012); Torrey et. al., J. Applied Physics, “Performance of a Split-Spectrum Photovoltaic Device Operating Under Time-Varying Spectral Conditions,” 109, 074909 (2011); Lin et. al., Conference Record of the IEEE Photovoltaic Specialists Conference “Lossless Holographic Spectrum Splitter in Lateral Photovoltaic Devices,” 2011; 000894-000898 (2011); Ludman et. al., First WCPEC, IEEE PVSC, pp 1208-1211, December 5-9 (1994); Green et al., “Forty three per cent composite split-spectrum concentrator solar cell efficiency,” Prog. Photovolt. Res. Appl. 2010, 18:42-47. Optical gratings arranged in stacks are described in U.S. Pat. No. 5,282,066.

Many technical challenges still burden the performance of photovoltaic devices that use multiple bandgap cell arrays in combination with spectrum splitting optics. Firstly, these systems are complex, particularly when using a larger number of arrayed cells or implementing concentration in combination with spectrum splitting, making it difficult to design and implement these devices. The complexity of the devices also makes it difficult to calculate and predict performance of the devices. Improvements in the performance of individual components, including improved photovoltaic efficiency for a range of cell bandgaps and improved optical efficiency for spectrum splitting optics, also are desired.

### SUMMARY

The present invention provides photovoltaic devices that comprise multiple bandgap cell arrays in combination with spectrum splitting optics. The spectrum splitting optics include two or more optical splitting, diffractive elements that are optically in series in a manner effective to successively and diffractively split incident light into segments or slices that are independently directed onto different photovoltaic cell(s) of the array having appropriate bandgap characteristics. For example, spectral slices with higher energy (shorter wavelengths) are selectively targeted onto cell(s) having higher bandgaps, while spectral slices with lower energy (longer wavelengths) are selectively targeted onto cell(s) having lower bandgaps.

The present invention accomplishes spectrum splitting using successive diffractive and transmissive optical elements in series. Diffractive optics coupled in series offer significant advantages compared to systems using primarily dichroic reflectors to accomplish spectrum splitting. It is true that photovoltaic modules using dichroic reflectors offer theoretical efficiencies of over 40%, but such reflectors incorporate 15 or more layers deposited using highly precise formation techniques. This means that dichroic reflectors by themselves are complicated, expensive optics. Diffractive elements, such as volume holographic gratings, can be much simpler in structure and more easily manufactured than dichroic reflectors. Photovoltaic modules using diffractive optics offer theoretical efficiencies in current designs approaching 40%, with the potential to reach 50% efficiency, while requiring less complexity and expense in the spectrum splitting elements. Diffractive elements also are easier to scale. By using diffractive transmission rather than reflection, corresponding PV modules can be in the same plane if desired to simplify overall design, architecture, and manufacture of resultant photovoltaic systems as a whole. Diffractive optical splitting elements can be fabricated in a variety of forms, including 2-D surface and 3-D volume index of refraction variations. This allows for tremendous design flexibility and also capacity for advancement as new manufacturing techniques develop. Transmissive diffractive elements, therefore, offer more design flexibility as compared to dichroic reflector-based systems.

As a consequence of successively splitting the incident light into spectral slices with a plurality of optical elements in series, as opposed to using a single, more-complex integrated optical element, the system can be more easily modeled and fabricated and delivers improved system efficiency. This makes it substantially easier to calculate and predict system performance, select optical components, formulate absorber compositions with appropriate bandgap characteristics, model and implement concentration, and the like.

“Transmissive” with respect to a diffractive optical element means that an incident light ray is incident upon a light incident surface of the element while a diffracted light ray derived from the incident light ray emerges from a different surface of the optical element. In many instances, the incident light ray is incident upon a first surface and the diffracted ray emerges from an opposite surface from the light incident surface. In contrast, in a reflective optical element, the light incident surface and the surface from which the corresponding reflected light emerges are the same. See Diffraction Grating Handbook, 6^{th} edition, Newport Corporation, page 20 (2005).

In one aspect, the present invention relates to a photovoltaic system that converts incident light into electrical energy, said system comprising:
(a) a photovoltaic array comprising a plurality of spatially (e.g., topographically) distributed photovoltaic members that are optically and electrically in parallel relative to each other and collectively have a range of bandgap characteristics, wherein each photovoltaic member incorporates one or more photovoltaic junctions in a manner such that the photovoltaic member has bandgap characteristics for a subset of the range of bandgap characteristics of the array;
(b) at least one spectrum splitting optical module comprising a plurality of spectrum splitting, transmissive, diffractive optical elements, wherein:
   (i) the spectrum splitting, diffractive optical elements are optically in series such that the spectrum splitting, transmissive, diffractive optical elements successively and diffractively split the incident light into a plurality of spatially separated, spectrally split bandwidth portions; and
   (ii) each bandwidth portion is associated with a subset of the photovoltaic members and is selectively targeted onto the associated subset of the photovoltaic members.

In one aspect, the present invention relates to a method of converting incident light into electrical energy, comprising the steps of:
(a) providing a photovoltaic array comprising a plurality of spatially distributed photovoltaic members that are optically and electrically in parallel relative to each other and collectively have a range of bandgap characteristics, wherein each photovoltaic member incorporates one or more photovoltaic junctions in a manner such that the photovoltaic member has bandgap characteristics for a subset of the range of bandgap characteristics of the array; and
(b) providing at least one optical spectrum splitting module comprising a plurality of spectrum splitting, transmissive, diffractive optical elements, wherein:
   (i) the spectrum splitting, transmissive, diffractive optical elements are optically in series such that the spectrum splitting, optical elements successively and diffractively split the incident light into a plurality of spatially separated, spectrally split bandwidth portions; and
   (ii) each bandwidth portion is associated with a subset of the photovoltaic members and is selectively targeted onto the associated subset of the photovoltaic members;
(c) providing a first photovoltaic member in a manner such that a first spectrally split bandwidth portion is selectively incident upon the first photovoltaic member relative to at least a second photovoltaic member; and
(d) providing a second photovoltaic member in a manner such that a second spectrally split bandwidth portion is selectively incident upon the second photovoltaic member relative to the first photovoltaic module.

In one aspect, the present invention relates to a method of converting incident light into electrical energy:
(a) providing at least one optical module comprising a plurality of spectrum splitting, transmissive, diffractive optical elements;
(b) using the spectrum splitting, transmissive, diffractive, optical elements to successively and diffractively split the incident light into a plurality of spatially and spectrally split bandwidth portions; and
(c) causing the bandwidth portions to be selectively targeted onto a plurality of photovoltaic members comprising spatially distributed bandgap characteristics, wherein the photovoltaic members optically and electrically in parallel relative to each other.

In one aspect, the present invention relates to a photovoltaic system that converts incident light into electrical energy, said system comprising:
(a) a photovoltaic array comprising a plurality of spatially distributed photovoltaic members that are optically and electrically in parallel relative to each other and collectively have a range of bandgap characteristics, wherein each photovoltaic member incorporates one or more photovoltaic junctions in a manner such that the photovoltaic member has bandgap characteristics for a subset of the range of bandgap characteristics of the array; and
(b) an array comprising a plurality of spectrum splitting optical modules, wherein:
   (i) at least first and second spectrum splitting optical modules comprise at least first and second spectrum splitting, transmissive, diffractive optical elements that are optically in series such that the optical elements successively and diffractively split the incident light into at least first and second, spatially distributed spectral bandwidth portions:
   (ii) each bandwidth portion is associated with a subset of the photovoltaic members and is selectively targeted onto the associated subset of the photovoltaic members; and
   (ii) a first photovoltaic member is positioned in a manner such that the first spectrally split spectral bandwidth portions from at least the first and second spectrum splitting optical modules are selectively and commonly incident upon the first photovoltaic module relative to a second photovoltaic member and the second photovoltaic member is positioned in a manner such that the second spectrally split spectral bandwidth portions from at least the first and second spectrum splitting optical modules are selectively and commonly incident upon the second photovoltaic member relative to the first photovoltaic member.

In one aspect, the present invention relates to a method of converting incident light into electrical energy:
(a) providing a first spectrum splitting optical module comprising at least first and second spectrum splitting, transmissive, diffractive optical elements;
(b) providing a second optical module comprising at least first and second spectrum splitting, transmissive, diffractive optical elements in series;
(c) using each of the first and second optical modules to successively and diffractively split the incident light into first and second optically and spatially split spectral bandwidth portions;
(d) causing the first spectrally split spectral bandwidth portions from the first and second optical modules to be selectively and commonly targeted onto at least a first photovoltaic member relative to at least a second photovoltaic member; and
(e) causing the second spectrally split spectral bandwidth portions from the first and second optical modules to be selectively and commonly targeted onto the second photovoltaic member relative to the first photovoltaic member.

### BRIEF DESCRIPTION OF THE DRAWINGS

FIG. 1 schematically shows one embodiment of a photovoltaic system of the present invention.

FIG. 2 schematically shows a perspective view of an alternative embodiment of the invention incorporating concentrating optics.

FIG. 3 schematically shows a side cross section view of the spectrum splitting optics and photovoltaic array incorporated into the device of FIG. 2.

FIG. 4 schematically shows a top view of the spectrum splitting optics array and photovoltaic array used in the device of FIG. 2.

FIG. 5 schematically shows an array of photovoltaic systems according to FIG. 2.

FIG. 6 schematically shows a perspective view of an alternative embodiment of the present invention.

FIG. 7 schematically shows a side cross-section view of the device shown in FIG. 6.

FIG. 8 schematically illustrates an embodiment of the present invention including orthogonal concentrators optically in series to concentrate spectrally split spectral slices onto corresponding photovoltaic cells.

FIG. 9 schematically illustrates an embodiment of the present invention in which photovoltaic devices are positioned in an array so that PV members with similar bandgap characteristics are generally adjacent to help improve photovoltaic light capture.

FIG. 10 schematically illustrates how the oriented devices of FIG. 9 are incorporated into a larger array so that PV members with similar bandgap characteristics are generally adjacent to help improve photovoltaic light capture.

### DETAILED DESCRIPTION

The embodiments of the present invention described below are not intended to be exhaustive or to limit the invention to the precise forms disclosed in the following detailed description. Rather the embodiments are chosen and described so that others skilled in the art may appreciate and understand the principles and practices of the present invention. All patents, pending patent applications, published patent applications, and technical articles cited throughout this specification are incorporated herein by reference in their respective entireties for all purposes.

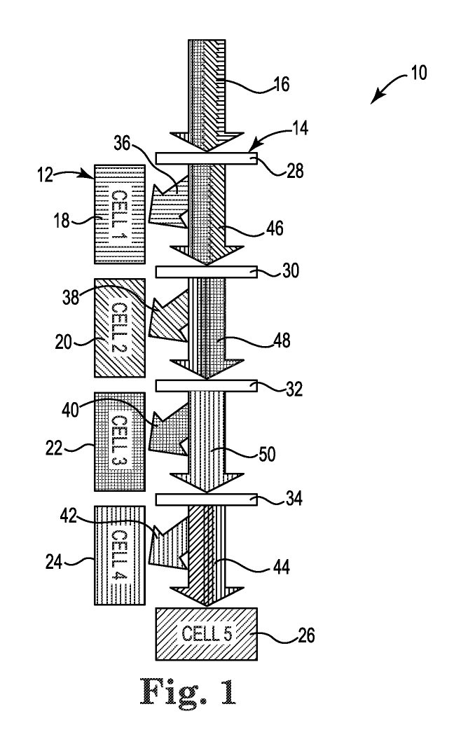

One embodiment of a photovoltaic system 10 of the present invention is schematically shown in FIG. 1. System 10 photovoltaically converts incident light 16 into electrical energy. System 10 includes as main components photovoltaic array 12 and spectrum splitting optical module 14.

The spectrum splitting optical module 14 is designed to spectrally split the incident light 16 into two or more spectral slices (also referred to as spectral bandwidth portions), e.g., 2 to 10 spectral slices in some embodiments, 2 to 8 spectral slices in some embodiments, 2 to 6 spectral slices in some embodiments, and 3 to 4 spectral slices in some embodiments For purposes of illustration, system 10 is described according to an illustrative mode of practice in which optical module 14 generates five spectral slices 36, 38, 40, 42, and 44 from incident light 16. For purposes of illustration, these are shown as ultraviolet/blue, green, yellow, orange/red, and infrared slices. The bandwidth of actual spectral slices may correspond to these colors or may correspond to other respective portions of the incident light 16. In actual practice, a greater or lesser number of spectral slices may be used.

The full spectral bandwidth of all the resultant slices obtained from incident light 16 may span a wide range of wavelengths. For example, spectral slices may be produced in some embodiments across a bandwidth that encompasses a range of wavelengths from ultraviolet light through infrared light or any portion(s) thereof. The wavelength span of each spectral slice may be generally the same as that for other slices. Alternatively, wavelength spans from slice to slice may vary.

Photovoltaic array 12 generally includes two or more photovoltaic members that are independently tuned to photovoltaically respond most efficiently to different, specific subsets of incident light 16 corresponding to the spectral slices produced by the spectrum splitting optical module 14. Desirably, at least a first photovoltaic member comprises at least a first photovoltaic cell that photovoltaically responds most efficiently to a first spectral bandwidth portion of the incident light relative to a second photovoltaic member, and the second photovoltaic member comprises at least a second photovoltaic cell that photovoltaically responds most efficiently to a second spectral bandwidth portion of the incident light relative to the first photovoltaic member. For purposes of illustration, array 12 includes five, differently tuned photovoltaic members 18, 20, 22, 24, and 26. Each of the five photovoltaic members independently may include single or multiple junction photovoltaic cells.

Tuning of the photovoltaic members 18, 20, 22, 24, and 26 is easily accomplished by incorporating photovoltaic junction(s) having appropriate bandgap characteristics into each photovoltaic member. Collectively, the bandgap characteristics of all the members 18, 20, 22, 24, and 26 may span a wide range, e.g. from about 0.5 eV to about 4.0 eV in some embodiments, but each photovoltaic member includes one or more photovoltaic junctions in a manner such that the member has bandgap characteristics for a subset of the full range of the array 12. Photovoltaic members with higher bandgap characteristics are tuned to photovoltaically respond most efficiently to spectral slices with higher energy (e.g., shorter wavelengths). Photovoltaic members with lower bandgap characteristics are tuned to photovoltaically respond most efficiently to spectral slices with lower energy (e.g., longer wavelengths).

For purposes of illustration, member 18 may be tuned (e.g., it has bandgap characteristics) to more efficiently respond photovoltaically to the spectral bandwidth portion of incident light including wavelengths associated with a spectral slice associated with wavelengths from 280 nm to 532 nm. Photovoltaic cells that are tuned to efficiently respond photovoltaically to a spectral bandwidth portion associated with this wavelength range may have bandgap characteristics of about 2.33 eV.

For purposes of illustration, member 20 may be tuned (e.g., it has bandgap characteristics) to more efficiently respond photovoltaically to the spectral bandwidth portion of incident light including wavelengths associated with wavelengths from 532 nm to 685 nm. Photovoltaic cells that are tuned to efficiently respond photovoltaically to a spectral bandwidth portion associated with this wavelength range may have bandgap characteristics of about 1.81 eV.

For purposes of illustration, member 22 is tuned (e.g., it has bandgap characteristics) to more efficiently respond photovoltaically to the spectral bandwidth portion of incident light including wavelengths associated with wavelengths from 685 nm to 899 nm. Photovoltaic cells that are tuned to efficiently respond photovoltaically to a spectral bandwidth portion associated with this wavelength range may have bandgap characteristics of about 1.38 eV.

For purposes of illustration, member 24 is tuned (e.g., it has bandgap characteristics) to more efficiently respond photovoltaically to the spectral bandwidth portion of incident light including wavelengths associated with wavelengths from 899 nm to 1240 nm. Photovoltaic cells that are tuned to efficiently respond photovoltaically to a spectral bandwidth portion associated with this wavelength range may have bandgap characteristics of about 1.00 eV.

For purposes of illustration, member 26 is tuned (e.g., it has bandgap characteristics) to more efficiently respond photovoltaically to the spectral bandwidth portion of incident light including wavelengths also associated with wavelengths from 1240 nm to 1771 nm. Photovoltaic cells that are tuned to efficiently respond photovoltaically to a spectral bandwidth portion associated with this wavelength range may have bandgap characteristics of about 0.70 eV.

Photovoltaic members 18, 20, 22, 24, and 26 are spatially distributed so that the spectral slices 36, 38, 40, 42, and 44 (described further below) may be selectively targeted onto different, associated subsets of the photovoltaic members 18, 20, 22, 24, and 26. To allow this kind of selective targeting, the light incident surfaces of the photovoltaic members 18, 20, 22, 24, and 26 are at least partially non-overlapping, preferably substantially entirely non overlapping, more preferably (as shown) are spatially separated and spaced apart such that at least some gap distance exists between adjacent light incident apertures to provide electrical isolation.

Spectrum splitting optical module 14 generally includes a plurality of spectrum splitting, diffractive optical elements 28, 30, 32, and 34 that are optically in series. Coupled this way, the optical elements 28, 30, 32, and 34 successively and diffractively split incident light 16 into spatially separated spectral bandwidth portions (described further below). “Spatially split” means that the bandwidth portions are generated as independent beams 36, 38, 40, 42, and 44, each of which is independently and selectively aimed toward the associated photovoltaic module 18, 20, 22, 24, or 26 designed to photovoltaically respond to the bandwidth portion associated with that split beam.

In operation, the four optical elements 28, 30, 32, and 34 successively and diffractively split incident light 16 into five beams 36, 38, 40, 42, and 44 that are selectively aimed onto photovoltaic members 18, 20, 22, 24, or 26, respectively. Initially, incident light 16 has a broad spectral bandwidth including multiple colors whose wavelengths include UV, visible, and IR colors. The optical elements 28, 30, 32, and 34 are arranged in series so that portions of the spectral bandwidth are successively split from main beam from higher energy to lower energy.

First, incident light 16 is spatially and spectrally split via diffraction by optical element 28 into separate beams 36 and 46. Optical element 28 is selected so that beam 36 constitutes predominantly light associated with wavelengths in the range from 280-532 nm and is directed at member 18, whose photovoltaic cell(s) are tuned to efficiently convert these wavelengths into electrical energy. Beam 46 includes the remainder of the spectral bandwidth and passes to optical element 30. The 280-532 nm band thus only has to go through a single optical element, which can be accomplished with de minimis losses of the short wavelength light, which contains a significant amount of energy in the solar spectrum. Otherwise, this color range may tend to be misallocated by interaction with higher diffraction orders in one or more other optical splitting elements if these short wavelength colors are split further downstream in the optical series.

Beam 46 is spatially and spectrally split via diffraction by optical element 30 into separate beams 38 and 48. Optical element 30 is selected so that beam 38 constitutes predominantly light associated with wavelengths from 532-685 nm and is directed at member 20, whose photovoltaic cell(s) are tuned to efficiently convert these wavelengths into electrical energy. Beam 48 includes the remainder of the optical bandwidth and passes to optical element 32.

Beam 48 is spatially and spectrally split via diffraction by optical element 32 into separate beams 40 and 50. Optical element 32 is selected so that beam 40 constitutes predominantly light associated with wavelengths from 685-899 nm and so that beam 40 is directed at member 22, whose photovoltaic cell(s) are tuned to efficiently convert these wavelengths into electrical energy. Beam 50 includes the remainder of the optical bandwidth and passes to optical element 34.

Beam 50 is spatially and spectrally split via diffraction by optical element 34 into separate beams 42 and 44. Optical element 34 is selected so that beam 42 constitutes predominantly light associated with wavelengths from 899-1240 nm and so that beam 42 is directed at member 24, whose photovoltaic cell(s) are tuned to efficiently convert these wavelengths into electrical energy. Beam 44 includes the remainder of the optical bandwidth. Because the higher energy colors were split from the main beam using optical elements 28, 30, 32, and 34, beam 44, from a practical perspective is a filtered beam composed predominantly of wavelengths from 1240-1771 nm. Beam 44 is directed to photovoltaic module 26, whose photovoltaic cell(s) are tuned to efficiently convert these wavelengths into electrical energy.

With this design, the wavelengths from 1240-1771 nm pass through all of the optical elements in the series. This is practical because these colors can pass through all of the elements with de minimis losses. Hence, a substantial portion of the energy from these long wavelength colors is still captured by the photovoltaic member 26 that is tuned to these colors. From a practical perspective, the ability to use the filtered beam 44 transmitted by the last optical element 34 in the series means that n+1 beams constituting specific spectral bandwidth portions or subsets of the incident light can be generated, where n is the number of optical elements optically in series.

System 10 operates at high efficiency at least in part because each photovoltaic member 18, 20, 22, 24, and 26 receives a specific subset of the spectral bandwidth associated with incident light 16 for which the photovoltaic member is tuned. Further, the spectrum splitting optics are coupled in series so that the incident light 16 is successively split into the specific spectral bandwidth portions. This enhances optical efficiency and also contributes to improved module efficiency.

Further, the incident light 16 is split in one dimension (also referred to as a linear distribution). Optical splitting in one dimension is easy to model using generalized coupled wave analysis (GCWA). This also allows the optical splitting and photovoltaic features to be more easily designed and selected using a linear distribution model. The stacked spectrum splitting optics are easier to model because each element may be designed to produce a single, specific spectral slice from the main beam of incident light. For example, one element might produce a spectral slice corresponding to blue color, while another might produce a spectral slice corresponding to red color, etc. The last element in the succession produces both an spectrally split slice as well as the filtered remainder of the main beam, wherein the remainder is a narrow spectral slice compared to the spectral bandwidth of the incident beam. For example, in one mode of practice after a series of optical elements successively produce spectral slices including UV, visible, and shorter wavelength near-IR colors, the remainder of the main beam has been filtered to be a narrow spectral slice associated with wavelengths from 1240-1771 nm.

In particular, such GCWA modeling can be used to identify the characteristics (e.g., phi, L, and D characteristics as defined below in Table 2) of diffractive, holographic light splitting gratings used as the light splitting optical elements 28, 30, 32, and 34 incorporated into the light splitting optical module 14. Exemplary modeling techniques to identify these characteristics are described in T. K. Gaylord & R. Magnuson, Journal of the Optical Society of America, pp 1165-1170 (1977) Vol. 67 Issue 9. Further, the use of a succession of optical elements in series to produce specific spectral slices allows light collection, light splitting, and light concentration functions to be more easily decoupled. If more complex spectrum splitting, diffractive elements are desired, other techniques, such as RCWA modeling, can be implemented in order to design and predict the performance of such optical elements. This method is described in E. N. Glytsis and T. K. Gaylord, “Rigorous 3-D coupled wave diffraction analysis of multiple superposed gratings in anisotropic media,” Applied Optics, 1989, Vol 28, pp 2401-2421.

As shown, photovoltaic members 18, 20, 22, 24, and 26 are shown as being perpendicular to the major faces of the optical elements 28, 30, 32, and 34. In actual practice, the photovoltaic members and optical elements can be mounted at other angle(s) as desired to achieve a variety of goals. For example, the angles between the photovoltaic members and optical elements relative to each other can be selected to optimize absorption of the spectral bandwidth portion at issue as well as to minimize losses due to reflection. Because a split beam may be generated at an angle that is a function of wavelengths of the split light beam, particularly when diffractive, holographic diffraction gratings are used as optical elements, the angles among the pairs of photovoltaic members and corresponding optical elements (e.g., photovoltaic member 18 and optical element 28 are a corresponding pair in that the 280-532 nm spectral slice 36 produced by element 28 is directed at member 18) may vary.

System 10 may incorporate optional concentrating optics (not shown) if desired. As one way to accomplish this, a concentrating optic may be positioned on one or more of the photovoltaic members 18, 20, 22, 24, and 26 so that the appropriate spectral slice is captured by the concentrating optic after spectrum splitting occurred to produce that slice. Generally, such a concentrating optic will have an inlet aperture larger than corresponding PV cell and a smaller outlet aperture whose size and shape is more closely matched to the corresponding PV cell.

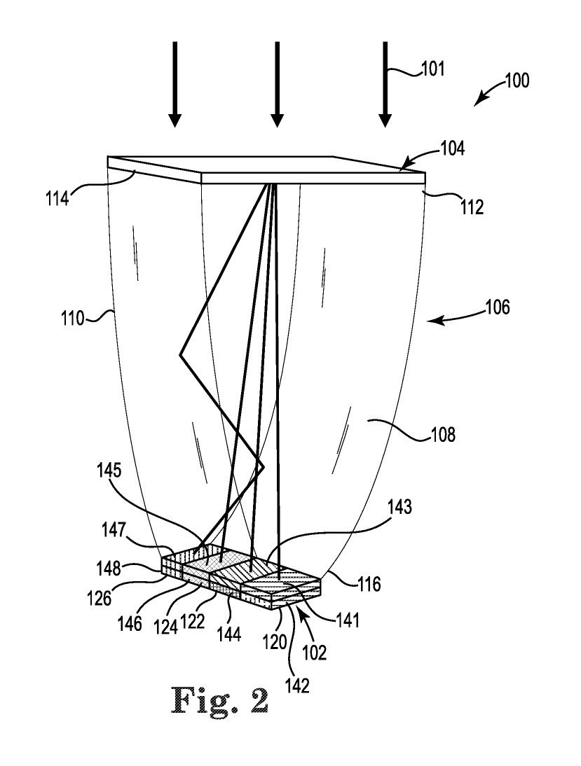

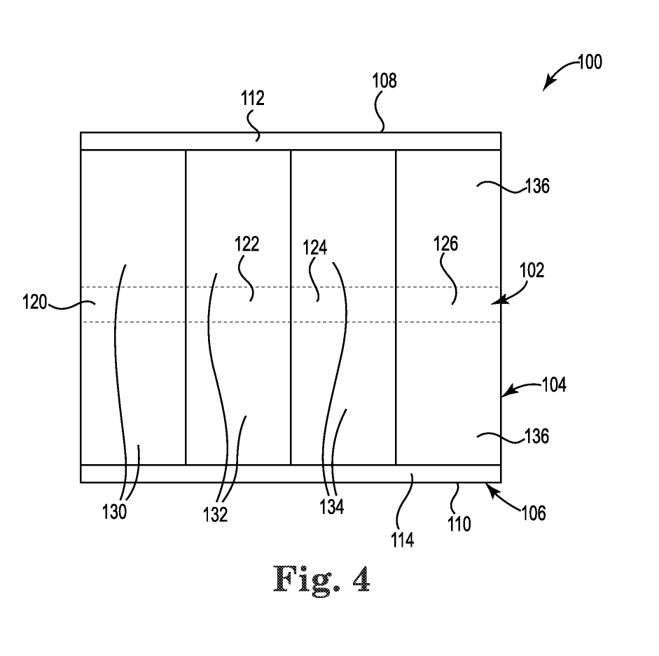

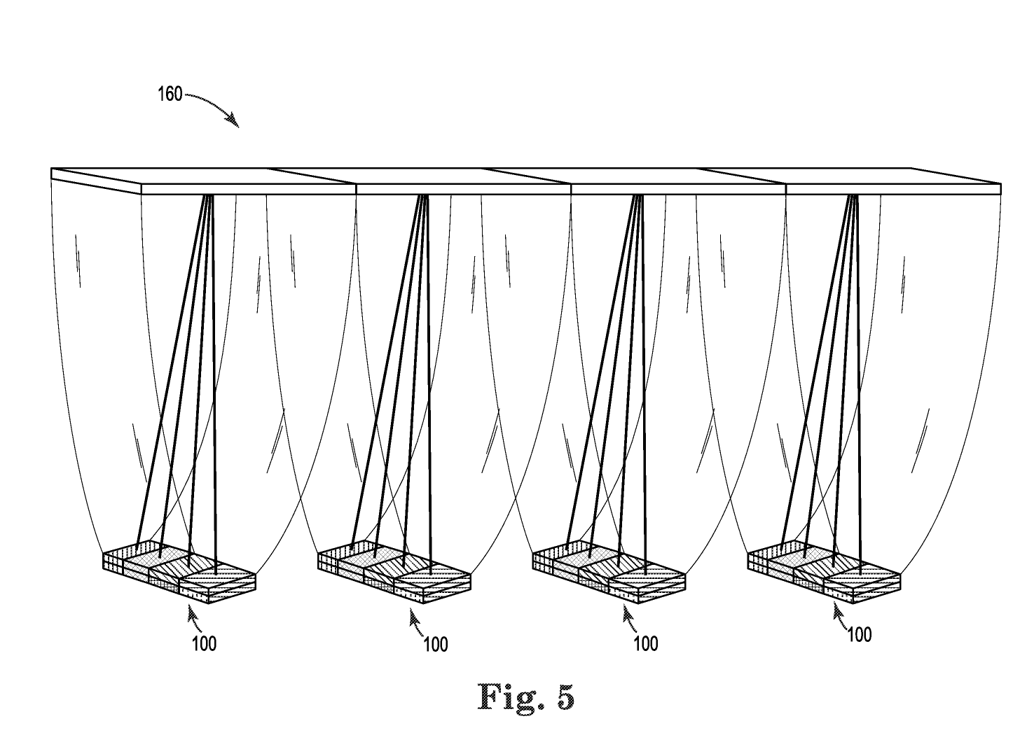

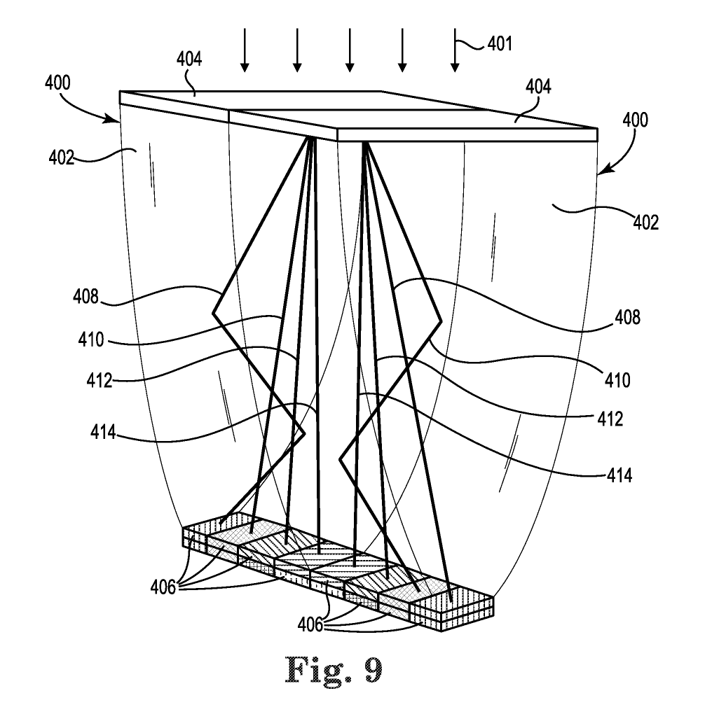

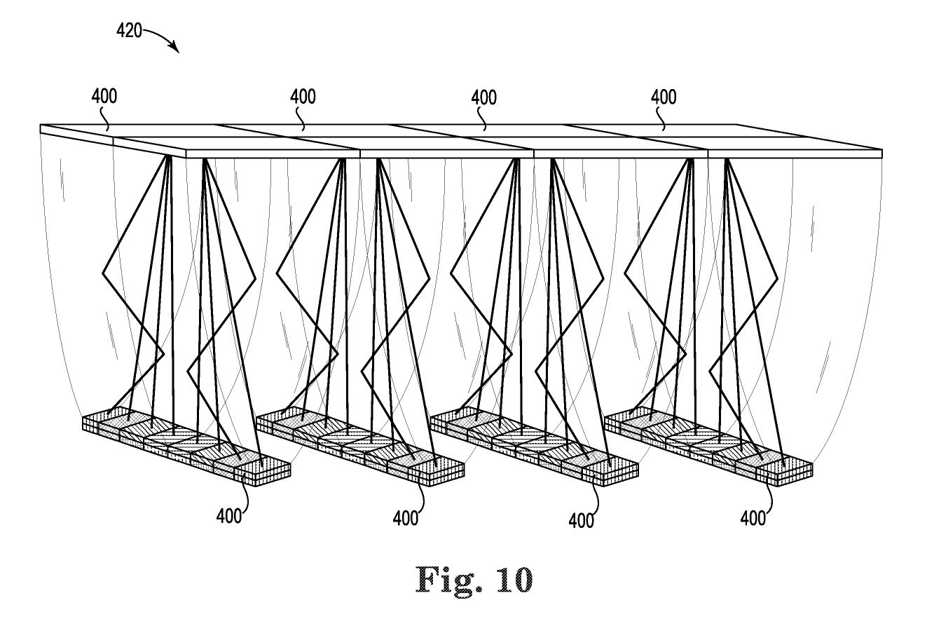

Another illustrative embodiment of a photovoltaic device 100 of the present invention is schematically shown in FIGS. 2, 3, 4, and 5. Device 100 photovoltaically converts incident light 101 into electrical energy. Device 100 includes as main components photovoltaic array 102, spectrum splitting optical array 104, and light concentrating optic 106. In one mode of actual practice, a plurality of devices 100 would be used in combination to provide a more comprehensive system 160 (as shown in FIG. 5 and another embodiment is described below with respect to FIGS. 9-10) for converting sunlight into electrical energy. Often groups of devices 100, would be mounted to a common framework (not shown) in a manner such that the grouped devices individually or in tandem track the sun.

Concentrating optic 106 is in the form of a trough, compound parabolic concentrator having sides 108 and 110 having top edges 112 and 114 and a bottom region 116. Side 110 is shown in phantom to allow photovoltaic array 102 to be seen behind side 110. Photovoltaic array 102 is positioned proximal to bottom region 116 in a manner so that spectral slices concentrated by optic 106 are incident upon the array 102. Spectrum splitting optical module 104 is positioned at the top edges 112 and 114. The area of the spectrum splitting optical module 104 serves as an inlet aperture of device 100. A trough, compound parabolic concentrator is only one kind of concentrating optic. Many other kinds of one dimensional or two dimensional concentrating optics may be used, if desired. It is important to note that concentrating optic 106 is placed below spectrum splitting optical module 104 so that light is first spectrally split into separate bandwidth portions and is then concentrated. Since the performance of diffractive optical elements is highly sensitive to the incident angle of incoming light, this approach (split first, then concentrate) helps to achieve large concentrations in photovoltaic modules featuring diffractive optics.

Concentrating optic 106 may have a concentrating power over a wide range. For example, the concentrating power of optic 106 for one-dimensional (1D) concentration may range from 1.2× to 50×, more preferably 1.2× to 20×. Lower levels of concentration, e.g., less than 50× and preferably less than 20×, are more preferred for one dimensional, concentrating optics, as these allow device 100 to be compact while minimizing the heat load and cost of components. In one mode of practice, optic 106 has a concentrating power of 12.2×, an acceptance angle of +/−3.8 degrees from normal, and a height of 8 cm (⅓ truncated relative to an untruncated structure having a concentration power of 15.1×). Concentration for two dimensional concentrating optics can be substantially higher, e.g., 200× to 1500×, for example.

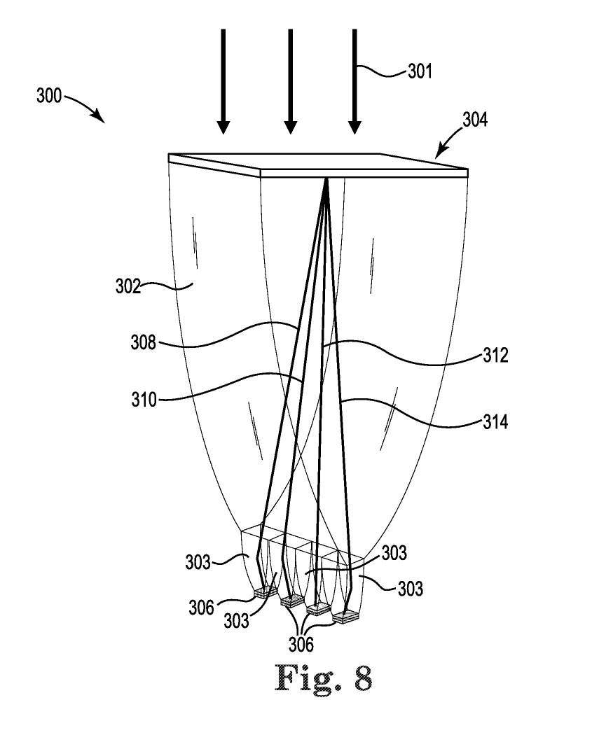

One dimensional concentrating optics can be coupled in series to achieve higher levels of concentration, if desired. An exemplary embodiment of the invention including concentrating optics that are orthogonally and optically in series is described below in FIG. 8. Optical and PV design is easier using orthogonal concentration. Orthogonal coupling of concentration optics also enhances spatial separation between the resultant spectral slices, enhances efficiency, and avoids using unduly narrow PV cells as might tend to result if a series of concentrating optics concentrates light in the same dimension to yield a long, narrow beam of concentrated light.

Photovoltaic array 102 includes a plurality of photovoltaic members that are tuned to different, specific spectral bandwidth portions of the incident light 101. For purposes of illustration, array 102 includes four photovoltaic members 120, 122, 124, and 126 that function as receivers for four corresponding spectral band width portions produced by each of optical modules 130, 132, 134, and 136 constituting spectrum splitting optical array 104. Collectively, the bandgap characteristics of all the photovoltaic members 120, 122, 124, and 126 may span a wide range, e.g. from about 0.8 eV to about 4.5 eV in some embodiments, but each photovoltaic member includes one or more photovoltaic junctions in a manner such that the member has bandgap characteristics for a subset of the full range of the array 102. Photovoltaic members with higher bandgap characteristics are tuned to photovoltaically respond most efficiently to spectral slices with higher energy (e.g., shorter wavelengths). Photovoltaic members with lower bandgap characteristics are tuned to photovoltaically respond most efficiently to spectral slices with lower energy (e.g., longer wavelengths).

In this embodiment, photovoltaic members 120, 122, 124, and 126 are co-planar in a plane that is below and generally parallel to the plane of the spectrum splitting optical array 104. Photovoltaic members 120, 122, 124, and 126 are spatially distributed so that the spectral slices (described further below) produced by spectrum splitting optical array 104 may be selectively targeted onto different, associated subsets of the photovoltaic members 120, 122, 124, and 126. To allow this kind of selective targeting, the light incident surfaces of the photovoltaic members 120, 122, 124, and 126 are at least partially non-overlapping, preferably substantially entirely non overlapping (as shown), more preferably are spatially separated and spaced apart such that at least some gap distance exists between adjacent light incident apertures.

Each of photovoltaic members 120, 122, 124, and 126 independently may include single junction or multiple junction photovoltaic cells. For purposes of illustration, each of photovoltaic members 120, 122, 124, and 126 are dual junction cells. Member 120 includes top cell 141 and bottom cell 142. Member 122 includes top cell 143 and bottom cell 144. Member 124 includes top cell 145 and bottom cell 146. Member 126 includes top cell 147 and bottom cell 148.

Preferably, the dual junction cells of each of photovoltaic members 120, 122, 124, and 126 are current and lattice matched to help optimize device performance. In an illustrative mode of practice, the members 120, 122, 124, and 126 are uniformly sized and form an array that is sized in the range from 0.5 to 50 mm×0.5 to 50 mm.

For purposes of illustration, member 120 is tuned (e.g., it has bandgap characteristics) to more efficiently respond photovoltaically to the spectral bandwidth portion of incident light including wavelengths from 280 nm to 674 nm. For purposes of illustration, member 122 is tuned (e.g., it has bandgap characteristics) to more efficiently respond photovoltaically to the spectral bandwidth portion of incident light including wavelengths from 674 nm to 873 nm. For purposes of illustration, member 124 is tuned (e.g., it has bandgap characteristics) to more efficiently respond photovoltaically to the spectral bandwidth portion of incident light including wavelengths from 873 nm to 1170 nm. For purposes of illustration, member 126 is tuned (e.g., it has bandgap characteristics) to more efficiently respond photovoltaically to the spectral bandwidth portion of incident light including wavelengths from 1170 nm to 1676 nm.

The following table shows bandgap and absorber compositions for an illustrative embodiment of photovoltaic array 102:

TABLE 1

| | Photovoltaic Member | | | |
|---|---|---|---|---|
| | 120 | 122 | 124 | 126 |
| Top junction | 2.25 | 1.60 | 1.23 | 0.93 |
| bandgap (eV) | | | | |
| Top junction | Al_{0.3}Ga_{0.22}In_{0.48}P | Al_{0.14}Ga_{0.86}As | In_{0.91}Ga_{0.09}As_{0.2}P_{0.8} | In_{0.71}Ga_{0.29}As_{0.62}P_{0.38} |
| composition | | | | |
| Bottom junction | 1.84 | 1.42 | 1.06 | 0.74 |
| band gap | | | | |
| Bottom junction | In_{0.51}Ga_{0.49}P | GaAs | In_{0.76}Ga_{0.24}As_{0.5}P_{0.5} | In_{0.53}Ga_{0.47}As |
| composition | | | | |
| Spectral Band | 280-674 | 675-873 | 874-1170 | 1171-1676 |
| (nm) | | | | |

Table 1 shows that the bandgap characteristics in each photovoltaic member do not overlap with the bandgap characteristics of any of the other members according to a preferred mode of practice. Indeed, the difference between the bandgap ranges of the photovoltaic members is at least 0.13 eV between the top junction of member 126 and the bottom junction of member 124 (i.e., the difference between 0.93 eV and 1.06 eV is 0.13 eV), and this difference becomes increasingly large between photovoltaic members (also referred to as subcells) tuned to higher energy light. The difference between the top junction of member (or subcell) 124 and the bottom junction of member (or subcell) 122 is 0.19 eV (1.42 eV minus 1.23 eV), and the difference between the top junction of member 122 and the bottom junction of member (or subcell) 120 is 0.24 eV (1.84 eV minus 1.60 eV). This shows how each member in this illustrative embodiment is tuned to be photovoltaically responsive to a particular and unique subset of the spectral bandwidth of the incident light 101.

Spectrum splitting optical array 104 includes a plurality of optical modules 130, 132,134 and 136 that optically and spatially split incident light into spectral bandwidth portions that are subsets of the full spectral bandwidth of incident light 101. Each module generates independent spectral split bandwidth portions that are aimed at photovoltaic members respectively tuned to the bandwidth portions. For example an optical module may be tuned to generate spectrally and diffractively split slices 171, 174, 173, and 172 that are then caused to target the corresponding photovoltaic members tuned to be responsive to the appropriate wavelength range of each slice.

Each optical module 130, 132, 134 and 136 includes a stack of optical splitting elements that are optically in series to successively and diffractively split the incident light into spatially split, spectral bandwidth portions. As illustrated, each optical module 130, 132, 134 and 136 includes a stack of three optical elements 151-162.

A wide variety of spectrum splitting optics may be used as the elements 151-162. In preferred embodiments, each element comprises a volume holographic grating that splits incident light via diffraction. Exemplary diffractive gratings include surface relief gratings and/or volume holographic gratings. In general, any two-dimensional or three-dimensional variation of the refractive index pattern in these optical splitting elements could be an appropriate transmissive, diffractive spectrum splitting optic. The following Table 2 shows exemplary grating parameters for holographic diffraction gratings constituting optical elements 151-162 for one embodiment of an optical array 104. This embodiment is designed to split incident light 101 into slices 171, 174, 173, and 172 from optical module 132, and slices of the same bandwidth emanating from the other optical modules 130, 134, and 136 that are commonly directed to the same respective subcells. These illustrative grating parameters are for gratings with an average refractive index of 1.3 and refractive index modulation of 0.02, which is realizable in materials such as dichromated gelatin.

TABLE 2

| | Photo- | Band- | Design | Phi | L | D |
|---|---|---|---|---|---|---|
| Optical | voltaic | width | λ | (de- | (microm- | (microm- |
| Module | Cell | (nm) | (nm) | grees) | eter) | eter) |
| 130 | 151 | 874-1170 | 1022 | −80.56 | 2.40 | 25.667 |
| | 152 | 1171-1676 | 1423 | −76.98 | 2.43 | 35.493 |
| | 153 | 675-873 | 774 | −85.00 | 3.42 | 20.907 |
| | Filtered | 300-674 | N/A | N/A | N/A | N/A |
| | pass- | | | | | |
| | through | | | | | |
| | band | | | | | |
| 132 | 154 | 300-674 | 487 | 85.00 | 2.15 | 13.160 |
| | 155 | 1171-1676 | 1423 | −80.56 | 3.34 | 35.747 |
| | 156 | 874-1170 | 1022 | −85.00 | 4.51 | 27.613 |
| | Filtered | 675-873 | N/A | N/A | N/A | N/A |
| | pass- | | | | | |
| | through | | | | | |
| | band | | | | | |
| 134 | 157 | 300-674 | 487 | 80.56 | 1.14 | 12.227 |
| | 158 | 675-873 | 774 | 85.00 | 3.42 | 20.907 |
| | 159 | 1171-1676 | 1423 | −85.00 | 6.28 | 38.440 |
| | Filtered | 874-1170 | N/A | N/A | N/A | N/A |
| | pass- | | | | | |
| | through | | | | | |
| | band | | | | | |
| 136 | 160 | 675-873 | 774 | 80.56 | 1.82 | 19.440 |
| | 161 | 300-674 | 487 | 76.98 | 0.83 | 12.147 |
| | 162 | 874-1170 | 1022 | 85.00 | 4.51 | 27.613 |
| | Filtered | 1171-1676 | N/A | N/A | N/A | N/A |
| | pass- | | | | | |
| | through | | | | | |
| | band | | | | | |

In Table 2, L is the period of refraction modulation in each simple sinusoidal volume, phase holographic grating. Phi is the tilt angle of the modulation of index of refraction with respect to the plane of the optical splitting element. D is the thickness of the holographic grating. The design wavelength λ is the central wavelength of the spectral band that the optical element is designed to diffract.

The optical elements in each optical module may be stacked in any order. For purposes of illustration, FIGS. 2-5 illustrate one possible mode for arranging stacks of optical elements according to the exemplary design of Table 3. Also for purposes of illustration, FIGS. 2-5 show how optical module 132 spatially splits incident light into four spectral bandwidth portions that are diffracted and concentrated in a manner to be targeted onto the four photovoltaic modules 120, 122, 124, and 126, respectively. In actual practice, the spectral bandwidth portions may be associated with different bandwidth portions of the incident light than those specified in Table 1, depending on the design. A greater or lesser number of spectral bandwidth portions and photovoltaic members may be used in other modes of practice, as well.

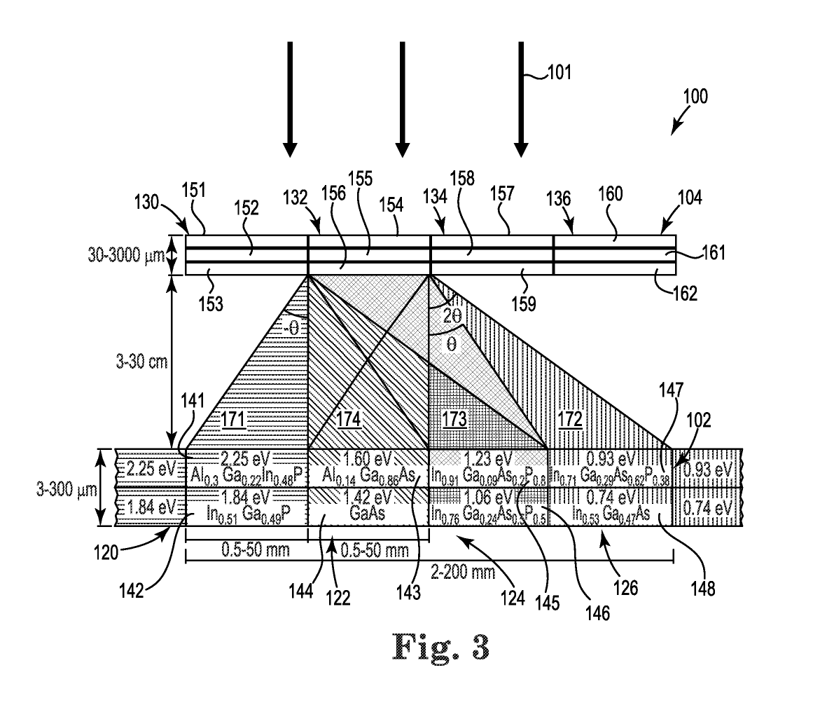

FIG. 3 shows how optical elements 154-156 of optical module 132 accomplish spectral splitting in the illustrated embodiment. Optical element 154 optically and diffractively splits incident light 101 to generate a spectral bandwidth portion 171 associated with wavelengths from 280 nm to 674 nm that is targeted onto photovoltaic subcell 120 that is tuned to be photovoltaically responsive to that spectral slice. Optical element 155 then successively and further splits the light to generate a spectral bandwidth portion 172 associated with wavelengths from 1171 nm to 1676 nm that is targeted onto photovoltaic subcell 126 that is tuned to be photovoltaically responsive to that spectral slice. Next, optical element 156 successively and further splits the light to generate a spectral bandwidth portion 173 associated with wavelengths from 873 nm to 1170 nm that is targeted onto photovoltaic subcell 124 that is tuned to be photovoltaically responsive to that spectral slice. The filtering action of the optical elements 154, 155, and 156 yields a spectral bandwidth portion 174 that is associated with wavelengths from 674 nm to 873 nm. This last beam passes through module 132 to target the photovoltaic subcell 122 below optical module 132. The other optical modules spectrally split the incident light 101 into successive spectral bandwidth portions to generate similar spectral slices that are commonly targeted onto respective photovoltaic subcells 120-126 in a similar manner according to the design parameters shown in Table 3.

Consequently, each optical module 130, 132, 134, and 136 generates spectral bandwidth portions that are targeted onto the correspondingly tuned photovoltaic subcells 120, 122, 124, and 126, respectively. For example, the 280-674 nm bandwidth portions generated by the optical modules 130, 132, 134, and 136 selectively and commonly target and are incident upon photovoltaic subcell 120. The 674-873 nm, 873-1170 nm, and 1170-1676 nm spectral bandwidth portions generated by the optical modules also selectively and commonly target and are incident upon the other photovoltaic subcells 122, 124, and 126 respectively, in a similar manner. Thus, each tuned photovoltaic subcell is irradiated by corresponding, multiple spectral bandwidth portions generated by all the optical modules 130, 132, 134, and 136. Advantageously, this means that the incident light 101 captured by the full aperture of device 100 is spectrally split in succession and directed onto correspondingly tuned photovoltaic modules to help enhance the overall efficiency of device 100.

Each optical module 130, 132, 134, and 136 generates four spectral bandwidth portions, and yet each optical module as illustrated includes a stack of three optical elements that are optically in series. Three of the four spectral slices are directed by diffractive action of the three optical elements, respectively. The fourth spectral bandwidth portion, in practical effect, results from filtering action by the stack of optical elements incorporated into each optical module. This filtered portion conveniently is targeted onto an underlying PV module. For example, if the stack of optical elements diffractively splits 280-674 nm, 674-873 nm, and 873-1170 nm wavelengths, the remainder of the incident light passing through the optical module is the 1171-1676 nm spectral bandwidth portion.

The design details shown in Tables 1 and 2 are based upon theoretical optical splitting provided by the grating stacks described in Table 3. The theoretical and actual performance of the gratings may differ. Accordingly, photovoltaic junctions 141-148 incorporated into subcells 120-126 can be tuned to be optimized for the actual spectral slices produced by the grating stack.

Device 100 may further include one or more optional features if desired. The light incident and exit surfaces of the spectrum splitting and PV optics may include antireflective coatings to help minimize optical losses due to reflection. Gaps or spaces between components may be filled with one or more optically transparent materials that help to minimize losses due to reflection at interfaces between materials of different index of refraction. Heat dissipating features such as fins or cooling media may be used to help dissipate heat. Coatings that reflect IR radiation may be used to help minimize heat build up. Abrasion resistant coatings and/or stain resistant coatings also may protect surfaces exposed to the ambient. Additional concentrating optics also may be used. For example, secondary concentrating optics may be used on the photovoltaic array 102 to further concentrate the spectral slices onto the photovoltaic cells in the array. Wiring, electrodes, and the like (not shown) may be used to electrically couple device 100 to other components in accordance with conventional practices as such exist currently or hereafter.

In some embodiments, a single power control may be used to control two or more, or even all, of the photovoltaic members 120, 122, 124, and 126 incorporated into photovoltaic array 102. However, it is more preferred if each module 120, 122, 124, and 126 has its own power control. Individual power controls are more desirable as it makes it easier to track the max power point of each photovoltaic subcell. Also, a drop or surge in current for one photovoltaic subcell is less likely to impact the performance of the other subcells. Also, independent power control makes it easier to maximize power delivered by each subcell under changing incident light spectral conditions (i.e. daily, seasonal, or weather-related changes).

Device 100 has many advantages. Device 100 has the potential to have very high theoretical efficiency in combination with light splitting optics. The high efficiency would be a result of effectively splitting the incident light such that each photovoltaic subcell receives a specific subset of the light spectrum from multiple optical sources. Device 100 also has the potential to offer high optical efficiency in terms of the power in incident light 101 can reach the appropriate subcells 120-126. The efficiency is enhanced by the successive light splitting provided by the series of optical elements stacked in each optical module 130, 132, 134, and 136. The successive light splitting minimizes cross-talk in the optical module and allows the device to be modeled as a linear distribution system using GCWA analytic tools for simple gratings. RCWA analytic tools would be more suitable for more complex diffractive optics, e.g., multiplex gratings, in other modes of practice. This simplifies the design and implementation of device 101. Further, the holographic diffraction gratings used as optical elements are available from many commercial sources and are inexpensive to produce in commercial quantities. Using tandem cells as shown in FIGS. 2-5 leverages the optical splitting. For example, using 4 tandem cells in combination with four spectral slices gives an effect substantially as if the incident light was split into eight slices, decreasing losses due to thermalization and incomplete absorption significantly compared to four single junction cells.

Additionally, device 100 has a design so that each spectrum splitting optical module 130, 132, 134, and 136 is in one plane and is optically coupled to at least one corresponding photovoltaic subcell that is spaced apart from and in a different plane from the optical module. Desirably, at least one concentrating optic is optically in series between the spectrum splitting function and the PV function. The planes of the optical module and the corresponding PV module may be parallel or nonparallel.

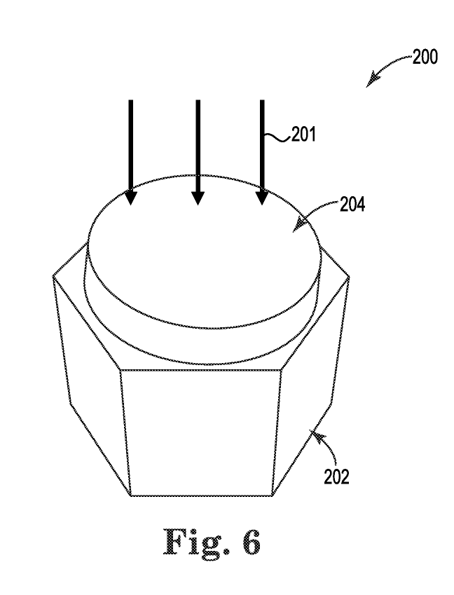

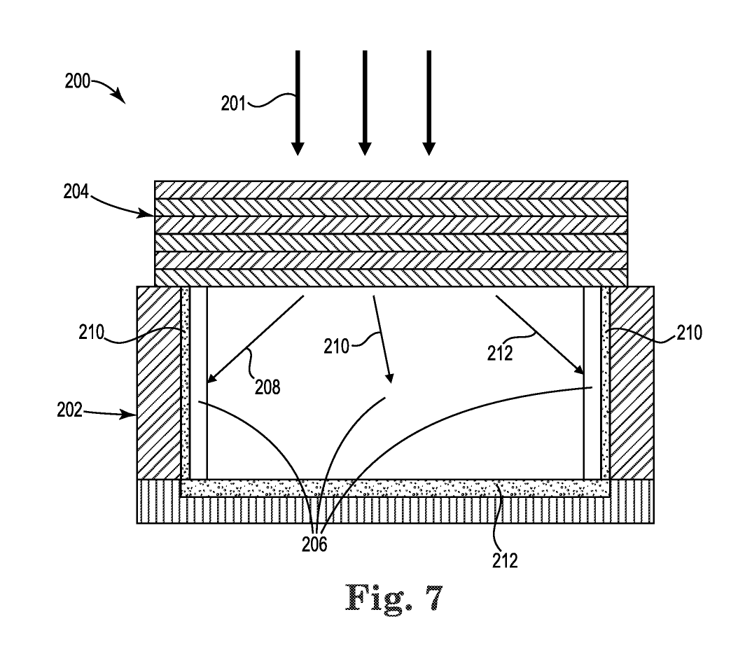

FIGS. 6 and 7 schematically illustrate an alternative embodiment of a device 200 of the present invention. Device 200 converts incident light 201 into, electrical energy. Device 200 includes as main components hexagonal housing 202, spectrum splitting optical module 204, and a photovoltaic array including photovoltaic subcells 206. Each photovoltaic subcell 206 is mounted to a respective face of hexagonal housing 202 and fills the full side panel of housing 202 on which the subcell is mounted. Reflective elements 210 are positioned between each subcell 206 and the housing 202 to help reflect non-absorbed light back toward the other subcells 206. A reflective element 212 also may be included on the bottom of housing 202 as well. An additional photovoltaic subcell (not shown) tuned to capture an additional spectral slice optionally can be mounted to reflective element 212, if desired. Each subcell 206 is tuned to a specific spectral bandwidth portion of the incident light 201.

Optical module 204 includes a stack of optical elements that successively split incident light 201 into spectral bandwidth portions 208, 210, and 212 (only three bandwidth portions are shown in the cross-section view of FIG. 6; three additional bandwidth portions, not shown, also are produced and aimed at the other three photovoltaic subcells 206 that cannot be seen in the cross-section view of FIG. 6) that are aimed at the corresponding photovoltaic subcells.

FIG. 8 schematically illustrates an alternative embodiment of a device 300 of the present invention. Device 300 converts incident light 301 into electrical energy. Device 300 includes primary concentrating optic in the form of reflecting trough 302 and secondary concentrating optics in the form of reflecting troughs 303. Each trough 303 is optically in series with the primary reflecting trough 302. Each trough 303 is oriented orthogonally relative to the trough 302. These troughs may be filled or may be hollow trough compound parabolic concentrators.

Device 300 also includes spectrum splitting optical module 304, and a photovoltaic array including photovoltaic subcells 306. Each photovoltaic subcell 306 is optically in series with the spectrum splitting optical module 304, the primary reflecting trough 302, and one of the corresponding secondary troughs 303.

Optical module 304 includes an array of stacks of optical elements that successively split incident light 301 into spectral bandwidth portions 308, 310, 312 and 314. For purposes of illustration, each of the spectral bandwidth portions is associated with particular colors blue, green, yellow, and red, respectively. These colors are for illustration purposes only, and other bandwidth portions may be used if desired, such as those used in device 100. Each bandwidth portion 308, 310, 312 and 314 is aimed at the corresponding photovoltaic subcell tuned for that bandwidth.

FIGS. 9-10 schematically illustrate a pair of devices 400 (similar to device 100 of FIG. 2) of the present invention oriented side by side in an aligned manner. Each device 400 converts incident light 401 into electrical energy. Device 400 includes primary concentrating optic in the form of reflecting trough 402. Device 400 also includes spectrum splitting optical module 404, and a photovoltaic array including photovoltaic subcells 406. Each photovoltaic subcell 406 is optically in series with the spectrum splitting optical module 404 and the primary reflecting trough 402.

Optical module 404 includes an array of stacks of optical elements that successively split incident light 401 into spectral bandwidth portions 408, 410, 412 and 414. For purposes of illustration, each of the spectral bandwidth portions is associated with particular colors blue, green, yellow, and red, respectively. These colors are for illustration purposes only, and other bandwidth portions may be used if desired, such as those used in device 400. Each bandwidth portion 408, 410, 412 and 414 is aimed at the corresponding photovoltaic subcell tuned for that bandwidth.

In one mode of actual practice, a plurality of devices 400 would be used in combination to provide a more comprehensive system 420 (as shown in FIG. 10) for converting sunlight into electrical energy. Often groups of devices 400, would be mounted to a common framework (not shown) in a manner such that the grouped devices individually or in tandem track the sun.

Advantageously, the orientation of devices 400 in system 420 is such that, along the axis of the subcells in each device, the subcells in one device are ordered from Subcell 1 to Subcell 4, but in the next device the ordering is reversed starting with Subcell 4 and ending with Subcell 1. In this manner, each subcell would have nearest neighbors receiving either the same spectral band or the next closest spectral band, reducing losses from photons arriving at the wrong subcell. In practical effect, the devices 400 are aligned head to head and tail to tail. FIG. 10 shows how devices oriented this way could be further incorporated into an n×n array (4×2 as illustrated) so that cells with similar tuning are neighbors. In illustrative embodiments, each n independently may range from 1 to 50, preferably 1-10, more preferably 2-8. This further maximizes useful capture of incident light. For example, consider a situation where a spectral band associated with blue light misses the associated blue-tuned subcell on one device. If the spectral band misses the targeted subcell to the right or left, the band may still be incident upon, and hence photovoltaically captured by, the blue-tuned subcell of a neighboring device on one side, or it may be incident on the green-tuned subcell of a neighboring device on its other side, which is far preferable to the light striking a yellow or red-tuned subcell.

The foregoing detailed description has been given for clarity of understanding only. No unnecessary limitations are to be understood therefrom. The invention is not limited to the exact details shown and described, for variations obvious to one skilled in the art will be included within the invention defined by the claims.

1. A photovoltaic system that converts incident light into electrical energy, said system comprising:
(a) a photovoltaic array comprising a plurality of spatially distributed photovoltaic members that are optically and electrically in parallel relative to each other and collectively have a range of bandgap characteristics, wherein each photovoltaic member incorporates one or more photovoltaic junctions in a manner such that the photovoltaic member has bandgap characteristics for a subset of the range of bandgap characteristics of the array;
(b) at least one spectrum splitting optical module comprising a plurality of spectrum splitting, transmissive, diffractive, non-reflective optical elements, wherein:
(i) the spectrum splitting, transmissive, diffractive, non-reflective optical elements are optically in series such that each of the spectrum splitting, transmissive, diffractive, non-reflective optical elements successively and diffractively splits the incident light into one of a plurality of spatially separated, spectrally split bandwidth portions; and
(ii) each bandwidth portion is associated with a subset of the photovoltaic members and is selectively targeted onto the associated subset of the photovoltaic members.

2. The system of claim 1, wherein at least one photovoltaic member comprises a plurality of photovoltaic junctions.

3. The system of claim 1, wherein the spectrum splitting optical module spectrally splits the incident light into at least four spectral bandwidth portions.

4. The system of claim 1, wherein each photovoltaic member comprises a light incident surface that is at least partially non-overlapping with at least one other light incident surface of said photovoltaic members.

5. The system of claim 1, wherein the spectrum splitting optical module comprises a stack including at least two spectrum splitting optical elements.

6. The system of claim 1, wherein at least one photovoltaic member has a light incident face that is nonparallel to a light incident face of the spectrum splitting optical module.

7. The system of claim 1, wherein at least one photovoltaic member has a light incident face that is substantially parallel to a light incident face of the spectrum splitting optical module and wherein the at least one photovoltaic member is physically spaced apart from the spectrum splitting optical module.

8. The system of claim 1, wherein at least a portion of the photovoltaic members comprise co-planar light incident faces, and wherein said photovoltaic members are in a plane that is parallel with a light incident surface of the spectrum splitting optical module.

9. The system of claim 1, wherein the photovoltaic array comprises a plurality of photovoltaic junctions collectively having a range of bandgap characteristics, and wherein each photovoltaic member has bandgap characteristics that are a subset of said range, and wherein at least one photovoltaic member has bandgap characteristics that are non-overlapping with respect to the bandgap characteristics of at least one other photovoltaic member.

10. The system of claim 1, wherein the system comprises at least first and second photovoltaic arrays that are positioned with respect to each other such that at least first and second photovoltaic members having substantially similar bandgap characteristics are adjacent.

11. The system of claim 1, comprising at least one concentrating optical element optically interposed between the spectrum splitting optical module and at least a portion of the photovoltaic array.

12. The system of claim 1, wherein the at least one spectrum splitting optical module comprises at least first and second spectrum splitting optical modules that comprise at least first and second spectrum splitting, transmissive, diffractive, non-reflective optical elements that are optically in series such that the optical elements successively and diffractively split the incident light into at least first and second, spatially distributed spectral bandwidth portions, and wherein a first photovoltaic member is positioned in a manner such that the first spectrally split spectral bandwidth portions from at least the first and second spectrum splitting optical modules are selectively and commonly incident upon the first photovoltaic module relative to a second photovoltaic member and the second photovoltaic member is positioned in a manner such that the second spectrally split spectral bandwidth portions from at least the first and second spectrum splitting optical modules are selectively and commonly incident upon the second photovoltaic member relative to the first photovoltaic member.

13. A method of converting incident light into electrical energy:
(a) providing at least one optical module comprising a plurality of spectrum splitting, transmissive, diffractive, non-reflective optical elements;
(b) using each of the spectrum splitting, transmissive, diffractive, non-reflective optical elements optically in series to successively and diffractively split the incident light into one of a plurality of spatially and spectrally split bandwidth portions, wherein each bandwidth portion is associated with a subset of the photovoltaic members and is selectively targeted onto the associated subset of the photovoltaic members;
(c) causing each of the bandwidth portions to be selectively targeted onto a plurality of photovoltaic members comprising spatially distributed bandgap characteristics.

14. The method of claim 13, comprising the steps of:
(d) providing a photovoltaic array comprising a plurality of spatially distributed photovoltaic members that are optically and electrically in parallel relative to each other and collectively have a range of bandgap characteristics, wherein each photovoltaic member incorporates one or more photovoltaic junctions in a manner such that the photovoltaic member has bandgap characteristics for a subset of the range of bandgap characteristics of the array;
(e) providing a first photovoltaic member in a manner such that a first spectrally split bandwidth portion is selectively incident upon the first photovoltaic member relative to at least a second photovoltaic member; and
(f) providing a second photovoltaic member in a manner such that a second spectrally split bandwidth portion is selectively incident upon the second photovoltaic member relative to the first photovoltaic module.

15. The method of claim 13, wherein step (a) further comprises providing a first spectrum splitting optical module comprising at least first and second spectrum splitting, transmissive, diffractive optical elements and providing a second optical module comprising at least first and second spectrum splitting, transmissive, diffractive optical elements coupled in series, wherein step (b) further comprises using each of the first and second optical modules to successively and diffractively split the incident light into first and second optically and spatially and spectrally split bandwidth portions, and wherein step (c) further comprises causing the first spectrally split spectral bandwidth portions from the first and second optical modules to be selectively and commonly targeted onto at least a first photovoltaic junction relative to at least a second photovoltaic junction, and causing the second spectrally split spectral bandwidth portions from the first and second optical modules to be selectively and commonly targeted onto the second photovoltaic junction relative to the first photovoltaic junction.
